(19) United States
(12) Patent Application Publication
(10) Pub. No.: US 2022/0357657 A1
(43) Pub. Date: Nov. 10, 2022

(54) COMPOSITION FOR PREPARING A COLOR FILTER

(71) Applicant: ALTANA AG, Wesel (DE)

(72) Inventors: Stephan Feser, Hamburg (DE); Denis Hervé Seuyep, Hamburg (DE)

(21) Appl. No.: 17/762,788

(22) PCT Filed: Sep. 15, 2020
(86) PCT No.: PCT/EP2020/075686

§ 371 Date: Mar. 23, 2022

(30) Foreign Application Priority Data
Sep. 27, 2019 (EP) 19200219.4

(51) Int. Cl. G03F 7/00; G03F 7/027

(52) U.S. Cl. CPC G03F 7/0007; G03F 7/027; G02B 5/223

(57) ABSTRACT

The invention relates to a composition comprising i) A colorant ii) A radical generating photoinitiator, iii) A polymer wherein at least 40 mol-% of the repeating units are units according to formula (I), [Formula should be inserted herm] wherein R¹ independently of each occurrence is H or CH₃, R² is a group of formula (II), [Formula should be inserted here] wherein L is a linking group, n is 0 or 1, and X independently of each occurrence is O or CH₂, R³ independently of each occurrence is selected from H, COOH, and a group of formula (II), iv) 0.0 to 10.0% by weight, calculated on the on the weight of the polymer iii), of one or ethylenically unsaturated polymerizable monomers having a molecular weight of less than 1500 g/mol.

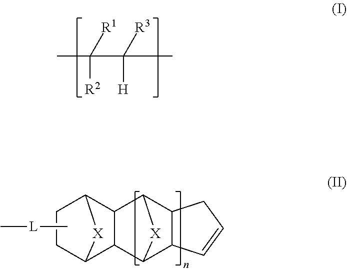

The invention relates to a composition suitable for preparing a color filter, to a process for preparing a color filter, to a color filter, and to a device comprising the color filter.

U.S. Pat. No. 9,075,305 describes photosensitive resin compositions for color filters. The compositions described in this document contain dicyclopentenyl-functional acrylic resins and low molecular weight ethylenically unsaturated compounds, in particular maleimides. The amount of low molecular weight maleimide in the compositions is relatively high. In some embodiments, the weight of low molecular weight maleimide exceeds the weight of dicyclopentenyl-functional acrylic resin. Incomplete conversion during curing of the composition may leave free low molecular weight maleimides in the cured composition. Low molecular weight maleimides have undesirable properties with respect human health. There is a need to minimize the use of and exposure to low molecular weight ethylenically unsaturated compounds in compositions. Furthermore, the solubility of imides in solvents typically used for compositions preparing color filters is limited.

WO 2017/085070 relates to crosslinkable polymers for dielectric layers in electronic devices. The polymers have olefinic dihydrodicyclopentadienyl functionalities in the side chain. The polymers are crosslinked using UV radiation. The crosslinkable polymers are suitable for preparing a dielectric layer, in particular for organic field effect transistors.

US 2012/0004341 describes an alkali soluble resin polymer and a photosensitive resin composition including the same. The alkali soluble resin is a copolymer of allyl methacrylate. The photosensitive resin composition comprises a monomer having ethylenically unsaturated polymerizable bonds.

The invention seeks to provide a composition suitable for preparing a color filter, in particular a patterned color filter. The composition should only contain a low content of low molecular weight ethylenically unsaturated compounds, preferably the composition should be essentially free of such compounds.

The invention provides a composition comprising
i) A colorant
ii) A radical generating photoinitiator,
iii) A polymer wherein at least 40 mol-% of the repeating units are units according to formula (I),

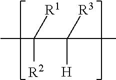

wherein
R¹ independently of each occurrence is H or CH₃,
R² is a group of formula (II),

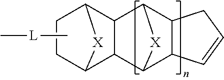

wherein L is a linking group, n is 0 or 1, and X independently of each occurrence is O or CH₂,
R³ independently of each occurrence is selected from H, COOH, and a group of formula (II),
iv) 0.0 to 10.0% by weight, calculated on the on the weight of the polymer iii), of one or more ethylenically unsaturated polymerizable monomers having a molecular weight of less than 1500 g/mol.

The composition of the invention is very suitable for preparing a color filter, in particular a patterned color filter. The composition can be formulated without addition of low molecular weight ethylenically unsaturated compounds.

Generally, the composition comprises from 0.0 to 10.0% by weight, calculated on the on the weight of the polymer iii), of one or more ethylenically unsaturated polymerizable monomers having a molecular weight of less than 1500 g/mol. In some embodiments, the composition may comprise an adhesion improving additive comprising alkoxysilane groups and ethylenically unsaturated polymerizable groups. Therefore, in preferred embodiments the weight limitation for component iv) relates to ethylenically unsaturated polymerizable monomers having a molecular weight of less than 1500 g/mol and having no alkoxysilane groups. In preferred embodiments the composition comprises 0.0 to 5.0% by weight, calculated on the on the weight of the polymer iii), of one or more ethylenically unsaturated polymerizable monomers having a molecular weight of less than 1500 g/mol and having no alkoxysilane groups. It is most preferred that the composition is free or essentially free of such monomers. Essentially free means that the composition does not contain ethylenically unsaturated polymerizable monomers having a molecular weight of less than 1500 g/mol and having no alkoxysilane groups in an amount that materially influences the properties of the composition. In some embodiments, the composition may contain small amounts of residual non-polymerized ethylenically unsaturated monomer from the preparation of polymer iii) in an amount of 0.0 to 1.5% by weight. Such amounts of ethylenically unsaturated polymerizable monomer do not materially influence the properties of the composition.

Examples of the ethylenically unsaturated polymerizable monomer iv) include unsaturated carboxylic acids such as (meth)acrylic acid, esters of aliphatic polyhydroxy compounds and unsaturated carboxylic acids, esters of aromatic polyhydroxy compounds and unsaturated carboxylic acids, esters obtained by an esterification reaction of unsaturated carboxylic acids or polyvalent carboxylic acids and polyhydric hydroxy compounds such as the above aliphatic polyhydroxy compounds and the aromatic polyhydroxy compounds, and ethylenically unsaturated compounds having a urethane skeleton, so-called urethane(meth)acrylates, which are preferably obtainable by reacting a polyisocyanate compound and a (meth)acryloyl group-containing hydroxy compound.

Specific examples are esters of aliphatic polyhydroxy compounds and unsaturated carboxylic acids including (meth)acrylic acid esters such as ethylene glycol di(meth)acrylate, triethylene glycol di(meth)acrylate, trimethylolpropane tri(meth)acrylate, trimethylolethane tri(meth)acrylate, pentaerythritol di(meth)acrylate, pentaerythritol tri(meth)acrylate, pentaerythritol tetra(meth)acrylate, dipentaerythritol tetra(meth)acrylate, dipentaerythritol penta(meth)acrylate, dipentaerythritol hexa(meth)acrylate, and glycerol (meth)acrylate. Further examples of the ethylenically unsaturated compound iv) include maleimides, having one or more maleimide group. Examples of such maleimides are described in U.S. Pat. No. 9,075,305, col. 6, I. 42 to col. 89, I. 40.

In order to prepare a color filter, the composition of the invention comprises a colorant. The colorant i) can be at least one pigment or at least one dye or a mixture of pigments or a mixture of at least one pigment and at least one dye, or a mixture of dyes. As the colorant in the inventive composition, a pigment is preferred. Organic and/or inorganic pigments can be used. Preferred are organic pigments. Colorants further include so-called dispersed dyes. In certain applications, a mixture of dyes is preferred for blue colors, a mixture of pigments is preferred for green colors, and a mixture of pigments or a mixture of pigment and dye is preferred for red colors.

Colors of a color filter are usually red, green or blue with a black matrix surrounding the pixels. Very often pigments are mixed to achieve the color of the certain pixel. For example, the green pixel composition can contain a blend of pigments with a green shade and a yellow shade.

Preferred organic pigments are diketopyrrolopyrrole-pigments, azo-pigments, phthalocyanine-pigments, quinacridone-pigments, benzimidazolone-pigments, isoindolinone-pigments, dioxazine-pigments, indanthrene-pigments, and perylene-pigments. The pigments can also be inorganic pigments.

Specific examples of suitable colorants are described in WO 2019/096891, p. 9, I. 30, to p. 13, I. 16.

It is preferable that the pigment(s) used as colorant have an average median particle diameter of 1 μm or less, preferably 0.3 μm or less, further preferably 50 nm or less determined by laser diffraction according ISO 13320:2009.

Generally, the amount of colorant in the composition is in the range of 20.0 to 60.0% by weight, calculated on the non-volatile content of the composition. The preferred amount of colorant in the composition depends on the type of colorant. Red colorants are preferably present in an amount of 30.0 to 35.0% by weight, calculated on the non-volatile content of the composition. Green colorants are preferably present in an amount of 40.0 to 50.0% by weight, calculated on the non-volatile content of the composition. Blue colorants are preferably present in an amount of 25.0 to 30.0% by weight, calculated on the non-volatile content of the composition.

The composition further comprises a radical generating photoinitiator.

A photoinitiator is often used as a mixture of a photopolymerization initiating agent, and a polymerization accelerator which is added, if necessary, and a component which absorbs light directly or is photosensitized to cause a degradation reaction or a hydrogen extraction reaction, and has the function of generating a polymerization active radical. Different kinds of photopolymerization initiating agents are well known in the literature and the inventive composition is not limited in terms of use of the different kinds of photopolymerization initiating agents in combination with the inventive composition. Examples of the photopolymerization initiator include thioxanthone derivatives, titanocene derivatives described in JP-A No. 59-152396, and JP-A No. 61-151197; hexaarylbiimidazole derivatives described in JP-A No. 10-300922, JP-A No. 11-174224, and JP-A No. 2000-56118; radical activating agents such as halomethylated oxadiazole derivatives, halomethyl-s-triazine derivatives, N-aryl-α-amino acids such as N-phenylglycine, N-aryl-α-amino acid salts, and N-aryl-α-amino acid esters, and α-aminoalkylphenone derivatives described in JP-A No. 10-39503; oxime ester-based derivatives described in JP-A No. 2000-80068. There is a trend towards using photopolymerization initiators which are active at higher wavelength, for example in the range of 365 to 405 nm.

Specific examples of suitable photoinitiators include benzophenone, 2-ethylanthraquinone, thioxanthone, 2-, 4-isopropylthioxanthone (isomers), 2-chlorothioxanthone, 1-chloro-4-propoxythioxanthone, 2-trifluoromethylthioxanthone, 2,4-bis(trichloromethyl)-6-methoxystyryl-s-triazine, (2,4,6-trimethylbenzoyl)-diphenylphosphine oxide, bis(2,4,6-trimethylbenzoyl)-phenylphosphine, 2,2′-bis(o-chlorophenyl)-4,4′,5,5′-tetraphenyl-1,2-biimidazole, 4-)-4′-methylphenylthio)benzophenone, 1-hydroxycydohexyl phenyl ketone, 2-(4-methylbenzyl)-2-(dimethylamino)-4-morpholinobutyrophenone), 1-[9-ethyl-6-(2-methylbenzoyl)-9H-carbazol-3-yl)ethanone 1 (O-acetyloxime) (OXE02), 2-(0-benzoyloxime)-1-[4-(phenylthio)phenyl]-1,2-octanedione (OXE01), 3-benzoyl-7-methoxycoumarin, benzil dimethyl ketal, 2,2-dimethoxy-2-phenylacetophenone, oligomeric 1-chloro-4-propoxythioxanthone (Speedcure 7010), 5-dibenzosuberenone and mixtures thereof.

Examples of the polymerization accelerator which is used, if necessary, include N,N-dialkylaminobenzoic acid alkyl esters such as N,N-dimethylaminobenzoic acid ethyl ester; mercapto compounds such as mercapto compounds having a heterocycle such as 2-mercaptobenzothiazole, 2-mercaptobenzoxazole and 2-mercaptobenzoimidazole; or aliphatic multifunctional mercapto compounds.

The photopolymerization initiating agents and polymerization accelerators may be used alone or in combination.

The composition further comprises a polymer iii) wherein at least 40 mol-% of the repeating units are units according to formula (I),

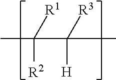

wherein
R¹ independently of each occurrence is H or CH₃,
R² is a group of formula (II),

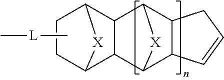

wherein L is a linking group, n is 0 or 1, and X independently of each occurrence is O or CH₂,
R³ independently of each occurrence is selected from H, COOH, and a group of formula (II).

Generally, 40.0 to 80.0 mol-% of the repeating units in polymer iii) are units according to formula (I). In preferred embodiments, at least 45.0 mol-% of the repeating units are units according to formula (I).

In some embodiments, it is preferred that in formula (II) n is 0. It is also preferred that X is CH₂.

The linking group L links the group of formula (II) to the polymer backbone. In preferred embodiments, the group L comprises an ester group. In some embodiments, the linking group comprises an ester group and an ether group. The linking group L is connected to the polycyclic system of the group of formula (II) via either of the carbon atoms of the bond crossed by the line protruding into the polycyclic system.

The polymer iii) used in accordance with the invention is suitably prepared via known polymerization processes of ethylenically unsaturated polymerizable monomers. Examples of polymerization processes include free radical polymerization with radical initiators, as well as controlled free radical polymerizations such as ATRP (Atom Transfer Radical Polymerization), RAFT (Reversible Addition Fragmentation Chain Transfer) or NMP (Nitroxide Mediated Polymerization).

The repeating units of formula (I) are suitably incorporated into the polymer by polymerization of ethylenically unsaturated polymerizable monomers having groups of formula (II). Examples of such monomers are represented by the following structures:

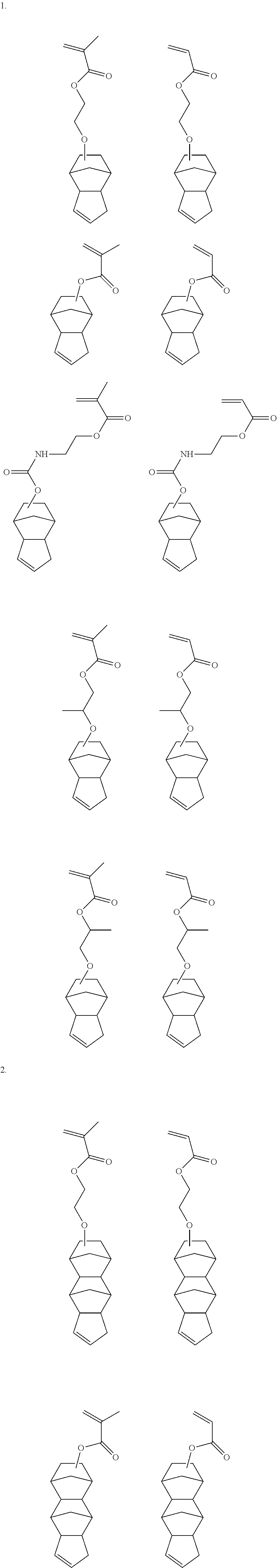

In addition to repeating units of formula (I), polymer iii) generally comprises other repeating units derived from other ethylenically unsaturated polymerizable monomers. Examples of such monomers include acrylic esters, methacrylic esters, acrylamides and/or methacrylamides. Herein the term “(meth)acryl” refers to both methacryl and acryl. The same applies for the term “(meth)acrylate” which refers to both methacrylate and acrylate, likewise. (Meth)acrylic esters of straight-chain, branched or cycloaliphatic alcohols having 1 to 22, preferably 1 to 12, more preferably 1 to 8 and most preferably 1 to 6 carbon atoms, such as methyl (meth)acrylate, ethyl (meth)acrylate, n-butyl (meth)acrylate, tert-butyl (meth)acrylate, n-hexyl (meth)acrylate, isobutyl (meth)acrylate, isopentyl (meth)acrylate, lauryl (meth)acrylate, 2-ethylhexyl (meth)acrylate, stearyl (meth)acrylate, cyclohexyl (meth)acrylate, behenyl (meth)acrylate, isodecyl (meth)acrylate, 2-propylheptyl (meth)acrylate, 3,5,5-trimethyl-1-hexyl (meth)acrylate, nonanyl (meth)acrylate, 2-propylheptyl (meth)acrylate, 2-isopropyl-5-methyl-hexyl (meth)acrylate, tridecyl (meth)acrylate, heptadecyl (meth)acrylate, heneicosanyl (meth)acrylate and isobornyl (meth)acrylate may be mentioned. Other suitable monomers are aryl (meth)acrylic esters whose aryl ring, without possible additional substituents, contains 5 to 12, preferably 6 to 10, carbon atoms, such as phenyl acrylate; and aralkyl (meth)acrylic esters whose aralkyl radical, without possible additional substituents on the aryl radical, contains 6 to 11, preferably 7 to 11, carbon atoms, such as benzyl (meth)acrylate. Other copolymerizable monomers include 2-hydroxyethyl (meth)acrylate, glycidyl (meth)acrylate, trimethoxysilylpropyl (meth)acrylate, N-phenyl maleimide, N-cyclohexyl maleimide and maleic anhydride. Other suitable monomers are vinyl aromatic compounds, such as styrene, and vinyl toluene, as well as vinyl esters.

In some embodiments, the repeating units of formula (I) may be prepared by modification of an existing polymer, for example by polymer-analogous reactions of commercially available polymers with hydroxy-dicyclopentadiene (DCPD-OH). Polymers particularly suitable for such reactions are those having carboxylic acid or carboxylic anhydride groups which can be esterified with DCPD-OH.

In one variant of the present invention, this is done using polymers selected from the group consisting of poly(styrene-co-maleic anhydride), poly(ethylene-co-maleic anhydride), poly(vinyl methyl ether-co-maleic anhydride), poly(octadecene-co-maleic anhydride), polyacrylic acid, polymethacrylic acid and mixtures thereof. When carboxylic anhydride-functional polymers are reacted with DCPD-OH, the dicylocpentadienyl group is linked to the polymer backbone via an ester group. In the reaction of DCPD-OH with carboxylic anhydride functional polymers generally a carboxylic acid group is formed, and the dicylocpentadienyl group is linked to the polymer backbone via an ester group. In this case, R³ in formula (I) is COOH. If the reaction is carried out at higher temperature, the removal of water, and/or a molar excess of DCPD-OH over carboxylic anhydride groups, further esterification of the formed carboxylic acid group may occur. In this case, R³ in formula (I) is a group of formula (II).

In preferred embodiments the polymer iii) used in the composition of the invention comprises acid groups. Acid groups in the polymer can render the polymer soluble in alkaline solutions. This property is relevant for dissolving uncured polymer in a process of preparing a patterned color filter. Examples of suitable acid groups are carboxylic acid groups, phosphoric acid groups or acidic phosphoric ester groups, sulfonic acid groups, and combinations thereof.

Among these, carboxylic acid group are preferred.

Suitably, the polymer iii) has an acid value in the range of 65 to 170 mg KOH/g, preferably 75 to 155 mg KOH/g.

The acid value can suitably be determined according to DIN EN ISO 2114 (June 2002).

In some embodiments, the acid groups of polymer iii) are directly connected to the main chain of the polymer. In preferred embodiments, the acid groups are present as pendant groups linked to the polymer main chain via a linking group. The linking group generally has at least 4 carbon atoms. Suitably, the linking group has 4 to 30 carbon atoms. In some embodiments, the linking group comprises an ester group.

The polymer iii) suitably has a weight average molecular weight Mw in the range of 15000 to 150000 g/mol. In preferred embodiments, the weight average molecular weight is in the range of 20000 to 80000 g/mol. The weight average molecular weight is suitably determined by gel permeation chromatography, using tetrahydrofuran as eluent and polystyrene as calibration standard.

It is known from the state of the art to include polyfunctional thiols in compositions comprising ethylenically unsaturated polymers to cause free-radical initiated curing. Polyfunctional thiols are organic compounds having two or more thiol groups. Thiols and polyfunctional thiols have unfavorable toxicological and olfactory properties. It is therefore preferred that the composition of the invention is free or essentially free of polyfunctional thiols. Essentially free of polyfunctional thiols means that the composition does not contain polyfunctional thiols in an amount that materially influences the properties of the composition. A composition comprising polyfunctional thiols in an amount of 0.0 to 0.2% by weight is generally considered to be essentially free of polyfunctional thiols.

The composition of the invention is generally liquid at a temperature of 23° C. To obtain a liquid composition and to adjust the viscosity to a desired level, the composition generally comprises a volatile organic solvent.

The organic solvent preferably has a boiling point at standard pressure (101.325 kPa) in a range of 80 to 300° C., more preferable a boiling point in the range of 100 to 250° C. The content of the organic solvent of the inventive composition is preferably 10 to 95% by weight, more preferably 60-90% by weight of the total weight of the inventive composition. Examples of such an organic solvent include glycol monoalkyl ethers such as ethylene glycolmonobutyl ether, propylene glycol monomethyl ether; glycol dialkyl ethers such as ethylene glycol diethyl ether, diethylene glycol dimethyl ether, diethylene glycol diethyl ether; glycol alkyl ether acetates such as ethylene glycol monomethyl ether acetate, ethylene glycol monoethyl ether acetate, propylene glycol monomethyl ether acetate, propylene glycol monoethyl ether acetate, propylene glycol monopropyl ether acetate, methoxybutyl acetate; dialkyl ethers such as diethyl ether; ketones such as acetone, methyl ethyl ketone, cyclohexanone; monohydric or polyhydric alcohols such as ethanol, propanol, butanol, hexanol, cyclohexanol, ethylene glycol, propylene glycol, diethylene glycol, dipropylene glycol, and glycerin; aliphatic hydrocarbons such as n-hexane; alicyclic hydrocarbons such as cyclohexane; aromatic hydrocarbons such as toluene, xylene, and cumene; linear or cyclic esters such as ethyl acetate, butyl acetate; nitriles such as acetonitrile, and benzonitrile or mixtures thereof. Also suitable are ethoxy ethyl propionate, and solvent blends containing n-butanol, for example blends of n-butanol and dimethyl sulfoxide.

Preferably, organic solvent is selected from the group consisting of glycol monoalkyl ethers, glycol dialkyl ethers, glycol alkyl ether acetates and mixtures thereof. Glycol alkyl ether acetates are even more preferred. Most preferred is propylene glycol monomethyl ether acetate. Glycol alkyl ether acetates may be used alone or in combination with other solvents.

In preferred embodiments, the composition of the invention comprises a dispersing agent for the colorant. Dispersing agents generally contain a binder affinic segment and one or more pigment affinic groups. Examples of pigment affinic groups include amine groups, quaternary ammonium groups, salts of amine groups, carboxylic acid groups, and phosphoric acid groups. Examples of suitable dispersing agents are described in numerous patent publications. JP 2009-25813 describes the use of aminic block co-polymers, consisting of acrylic esters and/or methacrylic esters, for the preparation of color resists, with an amine value in the range from 80 mg KOH/g to 150 mg KOH/g. U.S. Pat. No. 5,272,201 describes the use of methacrylate block co-polymers, which are prepared by means of Group Transfer Polymerization and comprise an aminic monomer in one block and an acidic monomer in the other block, as wetting agents and dispersants. In EP 2589614 pigmented UV-sensitive formulations with AB diblock co-polymer dispersants that contain at least one tertiary amino group and/or quaternary ammonium salt group as pigment affinic groups in one block and up to 10 mol-% monomers that contain a carboxylic acid group in the other block, are described. JP 2013053231 A describes a process of preparing AB diblock co-polymers by means of Group Transfer Polymerization formed from monomers consisting of acrylic esters and/or methacrylic esters in one block and acrylic esters and/or methacrylic esters bearing at least one amino group in the other block. Examples of suitable commercially available dispersing agents are available from BYK-Chemie GmbH under the trade designation DISPERBYK.

In preferred embodiments, the composition of the invention comprises a compound having one or more alkoxysilane groups. Alkoxysilane groups have the structure R—O—Si, wherein R represents an alkyl group. In preferred embodiments, R represents an alkyl group having 1 to 4 carbon atoms. In preferred embodiments, the compound having one or more alkoxysilane groups has at least one further functional group. The further functional group is suitably selected from epoxide group, primary or secondary amine group, and ethylenically unsaturated polymerizable group. Examples of compounds having one or more alkoxysilane groups include aminopropyl trimethoxy silane, aminopropyl triethoxy silane, vinyl triethoxy silane, methacryloxy propyl trimethoxy silane, acryloxy propyl trimethoxy silane, p-styryl trimethoxy silane, 3-methacryloxy propyl methyl dimethoxy silane, 3-methacryloxy propyl methyl diethoxy silane, glycidyloxy propyl trimethoxy silane, glycidyloxy propyl triethoxy silane and methacryloxy propyl trimethoxy silane.

In a preferred embodiment, the composition comprises
i) 20.0 to 60.0% by weight of a colorant
ii) 1.0 to 10.0% by weight of a photoinitiator
iii) 20.0 to 70.0% by weight of a polymer wherein 40.0 to 80.0 mol-% of the repeating units are units according to formula (I),

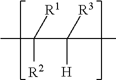

wherein
R¹ independently of each occurrence is H or CH₃,
R² is a group of formula (II),

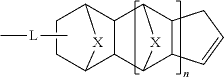

wherein L is a linking group, n is 0, and X is CH₂,
R³ is H,
and wherein the polymer has an acid value in the range of 65 to 170 mg KOH/g,
iv) 0.0 to 1.5% by weight of one or more ethylenically unsaturated polymerizable monomers having a molecular weight of less than 1500 g/mol,
v) 5.0 to 20.0% by weight of a dispersant for the colorant,
vi) 0.0 to 4.0% by weight of a compound having one or more alkoxysilane groups,
wherein the % by weight are calculated on the non-volatile content of the composition.

The composition of the invention is very suitable for preparing a color filter. Therefore, the invention also relates to a process for preparing a color filter. The process comprises the steps of
a) applying the composition according to the invention to a substrate and
b) curing selected areas of the applied composition by exposure to actinic radiation to create a pattern of cured and uncured areas of the applied composition.

Actinic radiation is radiation capable of triggering chemical reactions. Examples of actinic radiation are UV radiation and electron beam radiation. In a preferred embodiment, the process further comprises the step c) of dissolving the uncured areas of the applied composition by treatment with an alkaline liquid treatment agent.

The invention further relates to a color filter obtainable by the process of the invention, as well as to a liquid crystal display, a liquid crystal screen, a color resolution device or a sensor comprising the color filter.

### EXAMPLES

Raw Materials Used

| Name | Description | Source |
|---|---|---|
| PGMEA | 1-Methoxy-2-propylacetat, solvent | Sigma Aldrich |
| V-601 | Dimethyl 2,2′-azobis(2-methylpropionate), initiator | Wako Chemicals |
| FA-512M | Dicylcopentenyloxyethyl methacrylate | Hitachi Chemical |
| CD 535 | Dicylcopentenyl methacrylate | Sartomer |
| NK Ester SA | 2-Methacryloyloxyethyl succinate | Shin-Nakamura |
| MAA | Methacrylic acid | Sigma Aldrich |
| HEMA | 2-Hydroxyethyl acrylate | Sigma Aldrich |
| BzMA | Benzyl methacrylate | Sigma Aldrich |
| Irgaphor Red BT- | Colorant | BASF |
| CF | | |
| LP-N 21169 | Dispersant | BYK-Chemie |
| | | GmbH |
| TAZ-110 | 2,4-Bis(trichloromethyl)-6-(4-methoxystyryl)-1,3,5- | TCI, Europe |
| | triazine, Photo initiator | |
| OXE-02 | 1-[9-Ethyl-6-(2-methylbenzoyl)-9H-carbazol-3- | BASF |
| | yl]ethanone 1-(O-acetyloxime), Photo initiator | |
| Dynasilane | 3-Glycidyloxypropyltrimethoxysilane | Evonik |
| GLYMO | | |

Preparation of Polymers iii)

General procedure for preparation of polymers P1 to P8

Solvent PGMEA was placed into a reaction vessel under nitrogen atmosphere and heated to 100°.

The monomer mixture and initiator dissolved in 2 g PGMEA were separately metered in over a period of 120 min. After metering, the reaction was further continued for 60 min and a second dose of initiator dissolved in 1 g PGMEA was added dropwise. After further reaction of 180 min, the reaction mixture was cooled to room temperature. The polymer prepared are summarized in Table 1 below.

TABLE 1

| | | | | | | | | | | repeating |
|---|---|---|---|---|---|---|---|---|---|---|
| | | | NK | | | | | | | units of |
| | Monomer | Sartomer | Ester | | | | Initiator | Solvent | Mw, | formula |
| Polymer | FA-512M | CD 535 | SA | MAA | HEMA | BzMA | V-601 | PGMEA | g/mol | (I) |
| P1 | 19.7 g | | 11.6 g | | | | 0.43 g + 0.29 g | 94.0 g | 18368 | 60 mol % |
| P2 | 19.7 g | | 11.6 g | | | | 0.14 g + 0.29 g | 94.0 g | 49104 | 60 mol % |
| P3 | 19.2 g | | | 4.2 g | | | 0.42 g + 0.29 g | 94.0 g | 15960 | 60 mol % |
| P4 | 16.0 g | | 4.2 g | 3.7 g | | | 0.14 g + 0.29 g | 96.0 g | 34471 | 50 mol % |
| P5* | 17.1 g | | | 4.5 g | 1.7 g | | 0.15 g + 0.22 g | 93.0 g | 69580 | 50 mol % |
| P6 | 11.2 g | | 9.8 g | | | 3.8 g | 0.12 g + 0.24 g | 95.0 g | 35900 | 40 mol % |
| P7 | 8.0 g | 6.6 g | 9.37 g | | | | 0.35 g + 0.23 g | 96.0 g | 16213 | 60 mol % |
| P8 | 11.2 g | | 13.1 g | | | 7.5 g | 0.33 g + 0.33 g | 95.0 g | 24128 | 30 mol % |

*starting reaction temperature was 85° C., after 180 min subsequently increased to 100° C.

Preparation and Evaluation of Photocrosslinked Layers of Polymer P1-P8

The polymer solution was mixed with photoinitiator and PGMEA under stirring for 30 min. The solution was spun onto a pre-cleaned 1″ glass substrate at 1000 rpm. After prebake (90° C., 2 min) on a hotplate, the substrate was exposed to UV-light (100 mJ/cm², i-line). The substrate was then placed into a beaker containing 0.5% NaOH solution with 0.2% sodium dodecyl sulfate for 60 s and washed with de-ionized water. The film retention was determined from the ratio of the layer thickness of the dry films before and after immersion in the developer bath. The layer thickness was measured with the aid of a surface profilometer (Surface Profiler 150 Veeco) by scratching the film and determining the step height. The photocrosslinked layer of comparative polymer P8 containing 30 mol % DCPD repeating units exhibits poor film retention indicating insufficient crosslinking of the polymer.

| | Polymer | Photoinitiator | Photoinitiator | | Film |
|---|---|---|---|---|---|
| # | solution | OXE02 | TAZ-110 | PGMEA | retention |
| P1 | 5.00 g | — | 0.05 g | 1.25 g | 79% |
| P2 | 5.00 g | — | 0.05 g | 1.25 g | 90% |
| P2 | 5.00 g | 0.05 g | — | 1.25 g | 93% |
| P3 | 5.00 g | — | 0.04 g | — | 71% |
| P4 | 5.00 g | — | 0.05 g | 1.25 g | 84% |
| P4 | 5.00 g | 0.05 g | — | 1.25 g | 82% |
| P5 | 5.00 g | — | 0.04 g | 1.00 g + 0.67 g | 90% |
| | | | | n-BuOH | |
| P6 | 5.00 g | — | 0.05 g | 1.25 g | 81% |
| P7 | 5.00 g | — | 0.04 g | — | 76% |
| P8 | 5.00 g | — | 0.05 g | 1.25 g | 10% |

Preparation of Compositions According to the Invention

Composition 1

Preparation of Millbase MB1

7.5 g of Irgaphor Red BT-CF, 10.0 g of polymer solution P2, 5.6 g of LPN21169, 24.4 g of PGMEA and 2.5 g of n-butanol were put together in a glass bottle. 100 g of Zirconox beads were added and a dispersion process was performed in a LAU-disperser DA S200 over a period of time 4 h at 40° C.

20.0 g of MB1, 20.0 g of P2 and 0.32 g of photoinitiator TAZ-110 were mixed under stirring for 2 h and filtered through a 1-2 μm pore size syringe filter.

Composition 2

Preparation of Millbase MB2

7.5 g of Irgaphor Red BT-CF, 12.5 g of polymer solution P5, 5.6 g of LPN21169, 21.9 g of PGMEA and 2.5 g of n-butanol were put together in a glass bottle. 100 g of Zirconox beads were added and a dispersion process was performed in a LAU-disperser DA S200 over a period of time 4 h at 40° C.

20.0 g of MB2, 20.0 g of P5 and 0.32 g of photoinitiator TAZ-110 were mixed under stirring for 2 h and filtered through a 1-2 μm pore size syringe filter.

Composition 3

Preparation of Millbase MB3

7.5 g of Irgaphor Red BT-CF, 12.5 g of polymer solution P4, 5.6 g of LPN21169, 21.9 g of PGMEA and 2.5 g of n-butanol were mixed under stirring in a double-walled stainless steel container. 100 g of Zirconox beads were added and a dispersion process was performed with a dissolver Dispermat LC30 (VMA-Getzmann) over a period of time 10 h at 40° C.

20.0 g of MB3, 20.0 g of P4, 0.16 g of Dynasilane Glymo and 0.32 g of photoinitiator OXE02 were mixed under stirring for 2 h and filtered through a 1-2 μm pore size syringe filter.

Preparation of Color Filters

Color Filter 1

Composition 1 was spun onto a pre-cleaned 1″ glass substrate at 1000 rpm. After prebake (150° C., 2 min) on a hotplate, the substrate was covered with a shadow mask (USAF1951 resolution target) and exposed to UV-light (100 mJ/cm², i-line). The substrate was then placed into a beaker containing 0.5% NaOH solution with 0.2% sodium dodecyl sulfate for 120 s and washed with de-ionized water. The photo-patterned substrate was finally baked at 120° C. for 5 min. A minimum line width resolution of 7 μm at a film thickness of 1.3 μm was obtained.

Color Filter 2

Composition 2 was spun onto a pre-cleaned 1″ glass substrate at 2000 rpm. After prebake (120° C., 5 min) on a hotplate, the substrate was covered with a shadow mask (USAF1951 resolution target) and exposed to UV-light (200 mJ/cm², i-line). The substrate was then placed into a beaker containing 0.5% NaOH solution with 0.2% sodium dodecyl sulfate for 150 s and washed with de-ionized water. The photo-patterned substrate was finally baked at 120° C. for 5 min. A minimum line width resolution of 8 μm at a film thickness of 1.6 μm was obtained.

Color Filter 3

Composition 3 was spun onto a pre-cleaned 1″ glass substrate at 1500 rpm. After prebake (90° C., 2 min) on a hotplate, the substrate was covered with a shadow mask (USAF1951 resolution target) and exposed to UV-light (200 mJ/cm², i-line). The substrate was then placed into a beaker containing 0.5% NaOH solution with 0.2% sodium dodecyl sulfate for 100 s and washed with de-ionized water. The photo-patterned substrate was finally baked at 120° C. for 5 min. A minimum line width resolution of 10 μm at a film thickness of 1.5 μm was obtained.

It has been demonstrated that the composition of the invention is very suitable for preparing color filters without using substantial amounts of low molecular weight ethylenically unsaturated polymerizable monomers.

1. A composition comprising
i) a colorant
ii) a radical generating photoinitiator,
iii) a polymer wherein at least 40 mol-% of the repeating units are units according to the following formula (I), 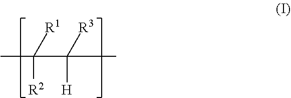
wherein
R¹ independently of each occurrence is H or CH₃,
R² is a group of the following formula (II), 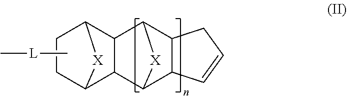
wherein L is a linking group, n is 0 or 1, and X independently of each occurrence is O or CH₂,
R³ independently of each occurrence is selected from H, COOH, and a group of formula (II), and
iv) 0.0 to 10.0% by weight, calculated on the on the weight of the polymer iii), of one or more ethylenically unsaturated polymerizable monomers having a molecular weight of less than 1500 g/mol.

2. The composition according to claim 1, wherein the composition comprises from 0.0 to 5.0% by weight, calculated on the weight of the polymer iii), of the one or more ethylenically unsaturated polymerizable monomers having a molecular weight of less than 1500 g/mol and having no alkoxysilane groups.

3. The composition according to claim 2, wherein the composition is substantially free of the one or more ethylenically unsaturated polymerizable monomers having a molecular weight of less than 1500 g/mol and having no alkoxysilane groups.

4. The composition according to claim 1, wherein the polymer iii) further comprises acid groups.

5. The composition according to claim 4, wherein the acid groups are carboxylic acid groups.

6. The composition according to claim 4, wherein polymer iii) has an acid value in the range of 65 to 170 mg KOH/g.

7. The composition according to claim 4, wherein the acid groups are linked to the polymer main chain of the polymer iii) via a linking group having at least 4 carbon atoms.

8. The composition according to claim 1, wherein the polymer iii) has a weight average molecular weight Mw in the range of 15000 to 150000 g/mol.

9. The composition according to claim 1, wherein the colorant comprises at least one of pigments and dyes.

10. The composition according to claim 1, wherein the composition is essentially free of polyfunctional thiols.

11. The composition according to claim 1, further comprising a dispersing agent for the colorant.

12. The composition according to claim 1, further comprising a compound having one or more alkoxysilane groups.

13. The composition according to claim 1, comprising
i) 20.0 to 60.0% by weight of the colorant
ii) 1.0 to 10.0% by weight of the radical generating photoinitiator
iii) 20.0 to 70.0% by weight of h polymer wherein 40.0 to 80.0 mol-% of the repeating units are units according to the following formula (I′) 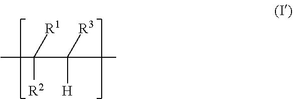
wherein
R¹ independently of each occurrence is H or CH₃,
R² is a group of formula (II′) 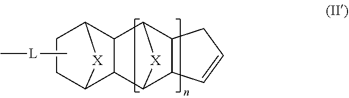
wherein L is a linking group, n is 0, and X is CH₂,
R³ is H,
and wherein the polymer has an acid value in the range of 65 to 170 mg KOH/g,
iv) 0.0 to 1.5% by weight of the one or more ethylenically unsaturated polymerizable monomers having a molecular weight of less than 1500 g/mol and having no alkoxysilane groups,
v) 5.0 to 20.0% by weight of a dispersant for the colorant,
vi) 0.0 to 4.0% by weight of a compound having one or more alkoxysilane groups
wherein the % by weight are calculated on the non-volatile content of the composition.

14. A process for preparing a color filter comprising
applying the composition according to claim 1 to a substrate and
curing selected areas of the applied composition by exposure to actinic radiation to create a pattern of cured and uncured areas of the applied composition.

15. The process according to claim 14, further comprising dissolving the uncured areas of the applied composition by treatment with an alkaline liquid treatment agent.

16. A color filter obtained by the process of claim 14.

17. A liquid crystal display comprising the color filter of claim 16.

18. A liquid crystal screen comprising the color filter of claim 16.

19. A color resolution device comprising the color filter of claim 16.

20. A sensor comprising the color filter of claim 16.
